(19) United States
(12) Patent Application Publication
(10) Pub. No.: US 2012/0187268 A1
(43) Pub. Date: Jul. 26, 2012

(54) FIXING DEVICE FOR POWER MODULE

(75) Inventor: HSIEH-CHOU LIAO, Tu-Cheng (TW)

(73) Assignee: HON HAI PRECISION INDUSTRY CO., LTD., Tu-Cheng (TW)

(21) Appl. No.: 13/050,953

(22) Filed: Mar. 18, 2011

(30) Foreign Application Priority Data
Jan. 25, 2011 (TW) 100102645

(51) Int. Cl. H05K 7/14

(52) U.S. Cl. 248/309.1

(57) ABSTRACT

A fixing device includes a casing and a power module fixed in the case by fasteners. The casing includes a bottom wall, a front wall perpendicularly extending from the bottom wall, and a plurality of first limiting blocks and a second limiting block. The first limiting blocks and the second limiting block project from the bottom wall. The first limiting blocks are arranged in two rows along a direction perpendicular to the front wall. The second limiting block is arranged along a direction parallel to the front wall. The second limiting block is positioned far from the front wall. The power module is in contact with the front wall, the first limiting blocks, and the second limiting block.

### BACKGROUND

1. Technical Field

The present disclosure relates to a fixing device for a power module.

2. Description of Related Art

In a container data center, a power module is usually fixed on a rack of the data center by screws, yet the screws may loosen after being used for a long period of time. Thus, the power module may vibrate too much and be damaged.

Thus, it is desirable to provide a fixing device for a power module that can overcome the described limitations.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure.

FIG. 1 is a schematic, exploded view of a fixing device for a power module in accordance with an embodiment.

FIG. 2 is a schematic, isometric view of the fixing device of FIG. 1.

FIG. 3 is a top view of the fixing device of FIG. 1.

### DETAILED DESCRIPTION

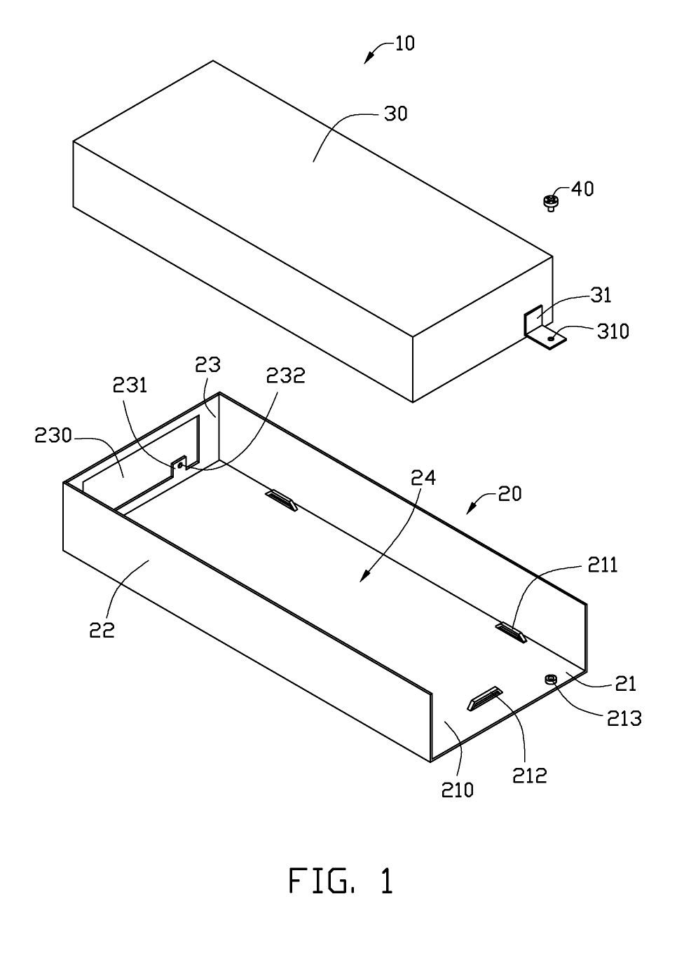

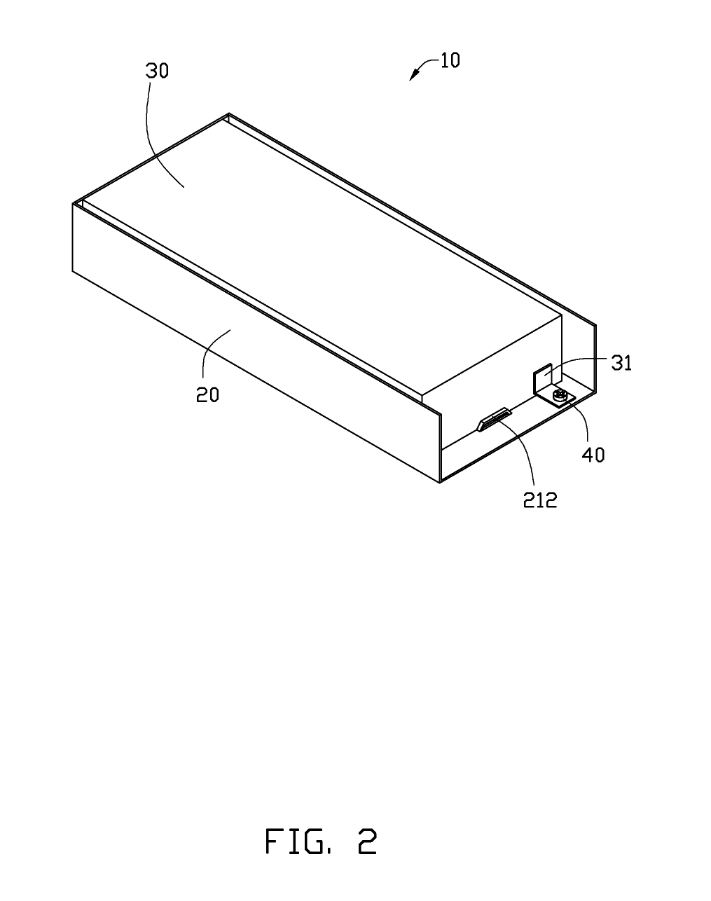

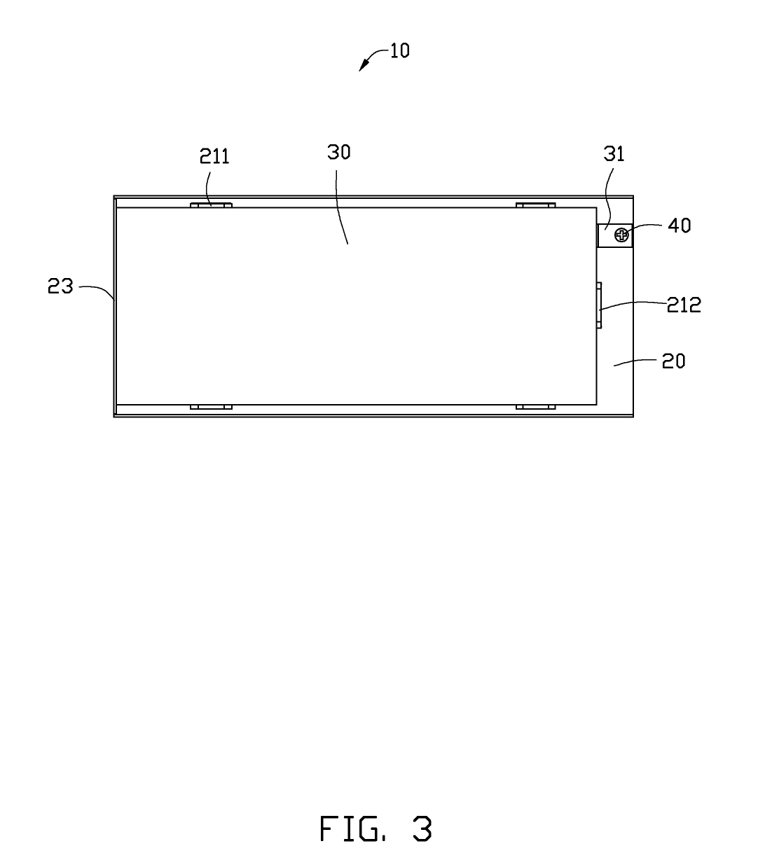

Referring to FIGS. 1 to 3, a fixing device 10 is shown. The fixing device 10 includes a casing 20 and a power module 30 mounted in the casing 20.

The casing 20 is mounted on a rack (not shown) by screws or other connecting means. The casing 20 includes a bottom wall 21, two sidewalls 22 extended upwardly from two opposite sides of the bottom wall 21, and a front wall 23 perpendicularly connected with the bottom wall 21 and the sidewalls 22. The bottom wall 21 includes a supporting surface 210 adjacent to the sidewalls 22 and the front wall 23. The supporting surface 210 is a flat plane. Four first limiting blocks 211 and a second limiting block 212 project from the supporting surface 210. The first limiting blocks 211 and the second limiting block 212 are long and narrow. The first limiting blocks 211 extend along a direction perpendicular to the front wall 23 at two rows. The second limiting block 212 is far from the front wall 23 relative to the first limiting blocks 211. The second limiting block 212 extends along a direction parallel to the front wall 23. The bottom wall 21 defines a threaded hole 213 far from the front wall 23 relative to the second limiting block 212.

The front wall 23 defines a cutout 230 corresponding to sockets and buttons of the power module 30. Two spaced fixing pieces 231 are formed in the cutout 230. Each of the fixing pieces 231 defines a fixing hole 232.

The power module 30 is rectangular shaped. An L-shaped fixing piece 31 is fixed on the power module 30 by screws (not shown). The fixing piece 31 defines a fixing hole 310.

The bottom wall 21, the front wall 23, the first limiting blocks 211, and the second limiting block 212 cooperate to form an accommodating space for receiving the power module 30. The power module 30 is in contact with the bottom wall 21, the front wall 23, the first limiting blocks 211, and the second limiting block 212 respectively. A fastener (such as a screw or a bolt) 40 extends through the fixing hole 310 and is engaged with the threaded hole 231. Other fasteners (not shown) extend through the fixing holes 232 and are engaged with threaded holes (not shown) in the power module 30. In this way, the power module 30 is fixed in the casing 20.

If the fasteners loosen, the power module 30 will not shake relative to the casing 20 because of the obstruction of the front wall 23, the first limiting blocks 211, and the second limiting block 212, thus damage from vibration may be avoided.

It will be understood that the above particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A fixing device comprising:
a casing comprising:
a bottom wall;
a front wall perpendicularly extended from the bottom wall;
a plurality of first limiting blocks projecting from the bottom wall and arranged in two rows along a direction perpendicular to the front wall; and
a second limiting block projecting from the bottom wall and positioned far from the front wall, the second limiting block arranged along a direction parallel to the front wall; and
a power module positioned in the case and surrounded by the front wall, the first limiting blocks, and the second limiting block, the power module being in contact with the front wall, the first limiting blocks, and the second limiting block.

2. The fixing device of claim 1, wherein the first limiting blocks and the second limiting block are long and narrow in shaped.

3. The fixing device of claim 1, wherein the bottom wall comprises a supporting surface adjacent to the front wall, and the supporting surface is a flat plane, the first limiting blocks and the second limiting block extend from the supporting surface.

4. The fixing device of claim 1, wherein the bottom wall defines a threaded hole adjacent to the second limiting block, the power module comprises a fixing piece, the fixing piece defines a fixing hole, the fixing device comprises a fastener, the fastener extends through the threaded hole and is engaged with the threaded hole.

5. The fixing device of claim 4, wherein the fixing piece is L-shaped and positioned on one end of the power module.
